(19) United States
(12) Patent Application Publication
(10) Pub. No.: US 2026/0068415 A1
(43) Pub. Date: Mar. 5, 2026

(54) LIGHT-EMITTING ELEMENT AND DISPLAY DEVICE HAVING THE LIGHT-EMITTING ELEMENT

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 19/280,824

(22) Filed: Jul. 25, 2025

(30) Foreign Application Priority Data
Aug. 29, 2024 (JP) 2024-147737

(51) Int. Cl. H10K 50/11; H10K 50/18; H10K 101/00; H10K 101/10; H10K 101/20; H10K 101/30

(52) U.S. Cl. CPC H10K 50/11; H10K 50/181; H10K 2101/10; H10K 2101/20; H10K 2101/27; H10K 2101/30

(57) ABSTRACT

A light-emitting element includes an anode, a cathode, and an electroluminescent layer between the anode and the cathode. The electroluminescent layer includes an emission layer containing a host material and a first fluorescent material. A bandgap of the host material is equal to or greater than 3.0 eV and equal to or less than 3.4 eV. A difference in a level of a lowest unoccupied molecular orbital between the host material and the first fluorescent material is equal to or greater than 1.0 eV. A difference in a level of a highest occupied molecular orbital between the host material and the first fluorescent material is equal to or less than 0.3 eV

### CROSS-REFERENCE TO RELATED APPLICATIONS

This application claims the benefit of priority to Japanese Patent Application No. 2024-147737, filed on Aug. 28, 2024, the entire contents of which are incorporated herein by reference.

### FIELD

An embodiment of the present invention relates to a light-emitting element and a display device having the light-emitting element.

### BACKGROUND

In recent years, display devices including organic light-emitting elements (OLEDs) have been widely used. In addition, organic electroluminescent elements exhibiting thermally activated delayed fluorescence or hyperfluorescence (registered trademark) have attracted attention because of their extremely high emission efficiency, and tremendous research and development are being conducted (see, for example, Japanese Laid-Open Patent Publications No. 2021-048366, 2020-013695, 2019-062127, and 2017-092329).

### SUMMARY

An embodiment of the present invention is a light-emitting element. The light-emitting element includes an anode, a cathode, and an electroluminescent layer between the anode and the cathode. The electroluminescent layer includes an emission layer containing a host material and a first fluorescent material. The first fluorescent material exhibits thermally activated delayed fluorescence. A bandgap of the host material is equal to or greater than 3.0 eV and equal to or less than 3.4 eV. A level of a lowest unoccupied molecular orbital of the host material is shallower than a level of a lowest unoccupied molecular orbital of the first fluorescent material, and a difference therebetween is equal to or less than 0.3 eV. A level of a highest occupied molecular orbital of the host material is shallower than a level of a highest occupied molecular orbital of the first fluorescent material, and a difference therebetween is equal to or greater than 1.0 eV.

An embodiment of the present invention is a display device. The display device includes a red-emissive pixel, a green-emissive pixel, and a blue-emissive pixel respectively including a red-emissive light-emitting element, a green-emissive light-emitting element, and a blue-emissive light-emitting element. The blue-emissive light-emitting element includes an anode, a cathode, and an electroluminescent layer between the anode and the cathode. The electroluminescent layer includes an emission layer containing a host material and a first fluorescent material. The first fluorescent material exhibits thermally activated delayed fluorescence. A bandgap of the host material is equal to or greater than 3.0 eV and equal to or less than 3.4 eV. A level of a lowest unoccupied molecular orbital of the host material is shallower than a level of a lowest unoccupied molecular orbital of the first fluorescent material, and a difference therebetween is equal to or less than 0.3 eV. A level of a highest occupied molecular orbital of the host material is shallower than a level of a highest occupied molecular orbital of the first fluorescent material, and a difference therebetween is equal to or greater than 1.0 eV.

### BRIEF DESCRIPTION OF DRAWINGS

FIG. 1 is a schematic cross-sectional view of a light-emitting element according to an embodiment of the present invention.

FIG. 2 is a schematic top view of a display device according to an embodiment of the present invention.

FIG. 3 is an equivalent circuit diagram of a pixel of a display device according to an embodiment of the present invention.

FIG. 4 is a schematic cross-sectional view of a light-emitting element disposed in a display device according to an embodiment of the present invention.

FIG. 5 is a schematic cross-sectional view of a display device according to an embodiment of the present invention.

FIG. 6 shows voltage-current density curves of the light-emitting elements of the Example and the Comparable Example.

FIG. 7 shows current density-normalized current efficiency (L/J) curves of the light-emitting elements of the Example and the Comparable Example.

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, the drawings are only an example, and do not limit the interpretation of the invention. In the specification and the drawings, the same reference number is provided to an element that is the same as that which appears in preceding drawings, and a detailed explanation may be omitted as appropriate.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a portion of the structure is not covered by the other structure and includes a mode where the portion uncovered by the other structure is further covered by another structure. In addition, the mode expressed by this expression includes a mode where the structure is not in contact with the other structure.

Hereinafter, blue emission refers to emission with a maximum emission peak wavelength in the range equal to or longer than 400 nm and equal to or shorter than 500 nm, green emission refers to emission with a maximum emission peak wavelength in the range equal to or longer than 500 nm and equal to or shorter than 650 nm, and red emission refers to emission with a maximum emission peak wavelength in the range equal to or longer than 650 nm and equal to or shorter than 750 nm.

### First Embodiment

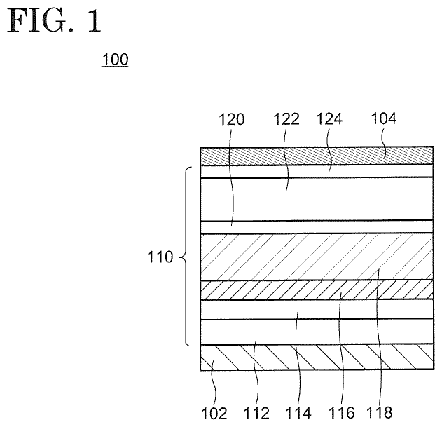

In this embodiment, an electroluminescent element (hereinafter, also simply referred to as a light-emitting element) 100 is described in accordance with one of the embodiments of the present invention. A schematic cross-sectional view of the light-emitting element 100 is shown in FIG. 1. The light-emitting element 100 is a blue-emissive light-emitting element. As shown in FIG. 1, the light-emitting element 100 has an anode 102 and a cathode 104 facing each other and includes an electroluminescent layer (hereinafter also referred to as an EL layer) 110 between the anode 102 and the cathode 104. The EL layer 110 is composed of a plurality of functional layers including organic compounds. The EL layer 118 has an emission layer 118 responsible for light emission and may further include other functional layers such as a hole-injection layer 112, a hole-transporting layer 114, an electron-blocking layer 116, a hole-blocking layer 120, an electron-transporting layer 122, an electron-injection layer 124, and the like. Preferably, the EL layer 110 has the emission layer 118 and the electron-blocking layer 116 located between the emission layer 118 and the anode 102 and in contact with the emission layer 118. The formation of a potential difference between the anode 102 and cathode 104 allows holes and electrons to be injected into the EL layer 110 from the anode 102 and the cathode 104, respectively, and these carriers are recombined in the emission layer 118. Once an emission material included in the emission layer 118 and capable of blue emission is excited by the recombination of holes and electrons, the energy released when this excited state returns to the ground state can be extracted as light. Hereinafter, each component is described below.

### 1. Anode and Cathode

The anode 102 is an electrode for injecting holes into the EL layer 110. When the light obtained in the EL layer 110 is extracted through the anode 102, the anode 102 is composed of a conductive oxide transmitting visible light such an indium-tin oxide (ITO) and indium-zinc oxide (IZO) because the anode 102 is configured to transmit visible light. On the other hand, when the light is extracted through the cathode 104, the anode 102 is configured to function as a reflective electrode efficiently reflecting light. In this case, the anode 102 is configured to include a metal with high reflectivity, such as silver and aluminum or an alloy thereof. For example, a configuration may be applied to the anode 102 in which a film containing a metal is sandwiched between films containing a conductive oxide.

The cathode 104 is an electrode for injecting electrons into the EL layer 110. When the light obtained in the EL layer 110 is extracted via the anode 102, the cathode 104 is configured to include the aforementioned metal or alloy (e.g., an alloy of silver and a metal having a low work function such as magnesium) because the cathode 104 also functions as a reflective electrode. Conversely, when the light obtained in the EL layer 110 is extracted through the cathode 104, the cathode 104 is configured to include a conductive oxide transmitting visible light. Alternatively, a metal-containing film having a thickness (e.g., equal to or greater than 5 nm and equal to or less than 20 nm) allowing visible light to pass therethrough may be used as the cathode 104. In the latter case, a film of a conductive oxide transmitting visible light may be further provided over the metal-containing film.

### 2. Hole-Injection Layer

The hole-injection layer 112 functions to promote hole injection from the anode 102 to the EL layer 110. A compound to which holes are readily injected, i.e., an electron-donating compound which is readily oxidized, can be used for the hole-injection layer 112. In other words, a compound with a shallow highest occupied molecular orbital (HOMO) level can be used. For example, aromatic amines such as benzidine derivatives and triarylamines, carbazole derivatives, thiophene derivatives, phthalocyanine derivatives such as copper phthalocyanine, aromatic hydrocarbons, and the like can be used. Alternatively, polymeric materials such as polythiophenes, polyanilines, and their derivatives can be used, and poly(ethylenedioxythiophene)/poly(styrenesulfonic acid) is represented as an example. A mixture of the aforementioned electron-donating compound such as aromatic amines, carbazole derivatives, and aromatic hydrocarbons with an electron acceptor may be used. The electron acceptors include transition metal oxides such as vanadium oxide and molybdenum oxide, nitrogen-containing heteroaromatic compounds, aromatic compounds with a strong electron-withdrawing group such as a cyano group, and the like. The hole-injection layer 112 may have a single-layer structure or may be composed of a plurality of layers containing different materials.

### 3. Hole-Transporting Layer

The hole-transporting layer 114 is provided so as to be in contact with the hole-injection layer 112. The hole-transporting layer 114 has a function of transporting the holes injected into the hole-injection layer 112 to the emission layer 118 side, and the same or similar materials as those usable in the hole-injection layer 112 may be used. For example, a material with a deeper HOMO level than the hole-injection layer 112, but with a difference therebetween of approximately 0.5 eV or less may be used. Typically, aromatic amines such as benzidine derivatives may be used. The hole-transporting layer 114 may also have a single-layer structure or may be composed of a plurality of layers containing different materials.

### 4. Electron-Blocking Layer

The electron-blocking layer 116 is provided so as to be in contact with the hole-transporting layer 114. The electron-blocking layer 116 confines the electrons injected from the anode 104 in the emission layer 118 by preventing them from passing through the emission layer 118 and from being injected into the hole-transporting layer 114 without contributing to recombination in the emission layer 118 and has a function to prevent the energy transfer of the excitation energy obtained in the emission layer 118 to the molecules in the hole-transporting layer 114. These functions prevent a decrease in emission efficiency.

The electron-blocking layer 116 contains or consists of an electron-blocking material. It is preferable to use a material as the electron-blocking material which has higher or comparable hole-transporting properties than electron transport properties and has a shallower lowest unoccupied molecular orbital (LUMO) level and a larger band gap than a host material (described below) in the emission layer 118. Preferably, the difference in LUMO levels between the electron-blocking material and the host material is greater than 0 eV and equal to or less than 0.1 eV or 0.2 eV. The increase in driving voltage is suppressed while suppressing the penetration of electrons through the emission layer 118 by setting a relatively small LUMO level difference between the electron-blocking layer 116 and the emission layer 118. It is also possible to prevent energy transfer from the emission layer 118 and suppress non-radiative recombination of carriers accumulated between these layers. The difference in HOMO level between the electron-blocking material and the host material may be arbitrarily determined, and the HOMO level of the electron-blocking material may be shallower or deeper than that of the host material. The difference therebetween may be set to be equal to or greater than 0.1 eV and equal to or less than 0.3 eV, for example.

Specific electron-blocking materials include aromatic amine derivatives, carbazole derivatives, 9,10-dihydroacridine derivatives, benzofuran derivatives, benzothiophene derivatives, and the like.

### 5. Emission Layer

The emission layer 118 contains a host material as a main component and a blue-emissive emission material (hereinafter, also referred to as a first fluorescent material) responsible for light emission. When the electron-blocking layer 116 is provided, the emission layer 118 is provided over and in contact with the electron-blocking layer 116. When the electron-blocking layer 116 is not used, the emission layer 118 may be formed over the hole-transporting layer 114 so as to be in contact with the hole-transporting layer 114.

A variety of compounds can be used as the host material, depending on the emission wavelength of the emission material. Preferably, host materials widely used in green-emissive phosphorescent light-emitting elements are used. Specifically, materials with a band gap equal to or greater than 3.0 eV and equal to or less than 3.4 eV are used. Moreover, it is preferable to use a material with a level of the lowest triplet excited state (Ti) of 1.9 eV or more and 2.5 eV or less. Furthermore, the host material is selected so that the LUMO level and the HOMO level thereof are shallower than the LUMO level and the HOMO level of the emission material, respectively. Specifically, the host material is selected so that the difference in LUMO level between the host material and the emission material is equal to or greater than 1 eV and the difference in HOMO level between the host material and the emission material is equal to or less than 0.3 eV. There is no restriction on the maximum value of the difference in LUMO level between the host material and the emission material, but it is, for example, equal to or less than 1.5 eV. Similarly, there is no restriction on the minimum value of the difference in HOMO level between the host material and the emission material, and it may be greater than 0 eV.

Furthermore, the host material is preferred to have higher hole transporting properties than electron-transporting properties. That is, it is preferable to use a compound with a higher hole mobility than its electron mobility as the host material. For example, a compound whose hole mobility is equal to or greater than 10 times and equal to or less than 1000 times or equal to or greater than 10 times and equal to or less than 100 times its electron mobility may be used as the host material.

It is possible to use, as specific host materials, oxadiazole derivatives, triazole derivatives, benzimidazole derivatives, quinoxaline derivatives, dibenzoquinoxaline derivatives, dibenzothiophene derivatives, dibenzofuran derivatives, pyrimidine derivatives, triazine derivatives, pyridine derivatives, bipyridine derivatives, phenanthroline derivatives, aromatic amine derivatives, carbazole derivatives, and the like in addition to zinc- and aluminum-based metal complexes.

Fluorescent materials exhibiting thermally activated delayed fluorescence (thermally activated delayed fluorescent materials) are used as the emission material (first fluorescent material). Thermally activated delayed fluorescent materials are compounds in which the T₁ level and the level of the lowest singlet excited state (S₁) are close to each other, and the difference therebetween is equal to or greater than meV and equal to or less than 20 meV. Therefore, the lowest triplet excited state of the emission material produced by carrier recombination is able to undergo reverse intersystem crossing to the lowest singlet excited state with very small thermal energy such as the energy corresponding to room temperature or lower. As a result, the rate of the non-radiative deactivation of the lowest triplet excited state is relatively reduced, and radiative deactivation from the lowest singlet excited state is promoted. This mechanism enables dramatic improvement of the efficiency of the light-emitting element 100. Because the emission occurs according to this mechanism, the thermally activated delayed fluorescent materials exhibit emission having a spectrum similar to that of normal fluorescence but with a significantly long lifetime. The fluorescence lifetime of the thermally activated delayed fluorescent materials is equal to or longer than 10⁻⁹ seconds (1 ns) and is preferably equal to or longer than 10⁻⁶ seconds (1 μs).

As the thermally activated delayed fluorescent materials, fullerenes and their derivatives, acridine derivatives such as proflavine, eosin, and the like are represented. In addition, metal-containing porphyrins containing magnesium, zinc, cadmium, tin, platinum, indium, or palladium are represented. Metal-containing porphyrins include, for example, protoporphyrin-tin fluoride complexes, mesoporphyrin-tin fluoride complexes, hematoporphyrin-tin fluoride complexes, coproporphyrin tetramethyl ester-tin fluoride complexes, an octaethylporphyrin-tin fluoride complex, ethioporphyrin-tin fluoride complexes, an octaethylporphyrin-platinum chloride complex, and the like.

In addition, compounds in which an electron-donor component and an electron-acceptor component are linked are represented as the thermally activated delayed fluorescent materials. A π-electron-excessive heteroaromatic ring and a π-electron-deficient heteroaromatic ring are represented as the electron-donor component and the electron-acceptor component, respectively. The basic skeletons of the π-electron-deficient heteroaromatic ring include a pyridine skeleton, a diazine skeleton, a triazine skeleton, and the like. The basic skeletons of the π-electron-excessive heteroaromatic ring include an acridine skeleton, a phenoxazine skeleton, a phenothiazine skeleton, a furan skeleton, a thiophene skeleton, a pyrrole skeleton, and the like. Such compounds include 2,4,5,6-tetra(9H-carbazol-9-yl)isophthalonitrile (4CzIPN), 2,4,5,6-tetra(3,6-dimethyl-9H-carbazol-9-yl)isophthalonitrile (m4CzIPN), 2,4,6-tri(4-diphenylaminophenyl)-1,3,5-tricyanobenzene (3DPA3CN), 2-[4-(10H-phenoxazin-10-yl)phenyl]-4,6-diphenyl-1,3,5-triazine (PXZ-TRZ), 2-(biphenyl-4-yl)-4,6-bis(12-phenylindolo[2,3-a]carbazole-11-yl)-1,3,5-triazine (PIC-TRZ), 2-[4-(10H-phenoxazine-10-yl)phenyl]-4,6-diphenyl-1,3,5-triazine (PXZ-TRZ), 10-[4-(4,6-diphenyl-1,3,5-triazine-2-yl)phenyl]-9,9-dimethyl-9,10-dihydroacridine (DMAC-TRZ), 2,4,5,6-tetrakis(3,6-di-t-butyl-9H-carbazol-9-yl)isophthalonitrile (t4XalPN), 2-{4-[3-(N-phenyl-9H-carbazol-3-yl)-9H-carbazol-9-yl]phenyl}-4,6-diphenyl-1,3,5-triazine (PCCzPTzn), 3-[4-(5-phenyl-5,10-dihydrophenazin-10-yl)phenyl]-4,5-diphenyl-1,2,4-triazole (PPZ-3TPT), 3-(9,9-dimethyl-9H-acridin-10-yl)-9H-xanthene-9-one (ACRXTN), bis[4-(9,9-dimethyl-9,10-dihydroacridine)phenyl]sulfone (DMAC-DPS), 10-phenyl-10H,10′H-spiro[acridine-9,9′-anthracene]-10′-one (ACRSA), and the like as examples.

The emission layer 118 may further include, in addition to the thermally activated delayed fluorescent material, an emission material (hereinafter, also referred to as a second fluorescent material) capable of transitioning from the ground state to the lowest singlet excited state upon receiving the lowest singlet excitation energy of the thermally activated delayed fluorescent material and providing blue emission through the radiative deactivation from the lowest singlet excited state. In the case where the second fluorescent material is not a compound exhibiting multiple resonance effects described below, the second fluorescent material is selected so that the S₁ level thereof is lower than that of the thermally activated delayed fluorescent material, i.e., the band gap thereof is smaller than that of the thermally activated delayed fluorescent material. The second fluorescent material is also selected so that the difference between the T₁ level and the S₁ level thereof exceeds 50 meV Hence, the second fluorescent material does not exhibit thermally activated delayed fluorescence in the light-emitting element 100 and exhibits a relatively short fluorescence lifetime (e.g., equal to or longer than 1 ρs and equal to or shorter than 1 ns). Examples of the second fluorescent material exhibiting such characteristics include fluorescent materials such as coumarin derivatives, quinacridone derivatives, pyrene derivatives, anthracene derivatives, and pyran derivatives exhibiting an emission maximum peak wavelength in the region equal to or longer than 400 nm and equal to or shorter than 500 nm. In general, the emission spectra exhibited by thermally activated delayed fluorescent materials are broad and have low color purity. In contrast, the fluorescent materials described above are able to emit light with high color purity because they provide emission spectra with a relatively narrow full width at half maximum. Therefore, it is possible to provide a light-emitting element 100 showing not only high emission efficiency due to the thermally activated delayed fluorescent material but also excellent color purity by adding the second fluorescent material to the emission layer 118.

Furthermore, a compound exhibiting a multiple resonance effect may be used as the second fluorescent material in the emission layer 118. The multiple resonance effect is an effect in which a heteroatom such as boron and nitrogen is incorporated into a π-electron conjugation system of carbon, thereby increasing the contribution of resonance structures having an anion and a cation. Therefore, a compound which contains a heteroatom such as boron and nitrogen incorporated into a π-electron conjugation system of carbon may be used as the second fluorescent material in the light-emitting element 100. This configuration further promotes the reverse intersystem crossing from the lowest triplet excited state to the lowest singlet excited state, resulting in improved emission efficiency. In addition, it is also possible to narrow the emission spectrum and improve color purity because the compounds exhibiting a multiple resonance effect also provide an emission spectrum with a relatively narrow full width at half maximum.

The compounds exhibiting the multiple resonance effect include, for example, condensed heteroaromatic compounds containing nitrogen and boron, such as 5,9-diphenyl-5,9-diaza-13b-boranaphtho[3,2,1-de]anthracene (DABNA1), 9-([1,1′-diphenyl]-3-yl)-N,N,5,11-tetraphenyl-5,9-dihydro-5,9-diaza-13b-boranaphtho[3,2,1-de]anthracen-3-amine (DABNA2), 2,12-di(tert-butyl)-5,9-di(4-tert-butylphenyl)-N,N-diphenyl-5H,9H-[1,4]benzazaborino[2,3,4-kl]phenazaborin-7-amine (DPhA-tBu4DABNA), 2,12-di(tert-butyl)-N,N,5,9-tetra(4-tert-butylphenyl)-5H,9H-[1,4]benzazaborino[2,3,4-kl]phenazaboroline-7-amine (tBuDPhA-tBu4DABNA), 2,12-di(tert-butyl)-5,9-di(4-tert-butylphenyl)-7-methyl-5H,9H-[1,4]benzazaborino[2,3,4-kl]phenazaboroline (Me-tBu4DABNA), and N7,N7,N13,N13,5,9,11,15-octaphenyl-5H,9H,11H,15H-[1,4]benzazaborino[2,3,4kl][1,4]benzazaborino[4′,3′,2′:4,5][1,4]benzazaborino[3,2-b]phenazaborin-7,13-diamine (v-DABNA).

Among the above-mentioned compounds, thermally activated delayed fluorescent materials with an emission maximum peak wavelength equal to or longer than 400 nm and equal to or shorter than 500 nm are used as the emission material in the light-emitting element 100.

### 6. Hole-Blocking Layer

The hole-blocking layer 120 confines the holes injected from the anode 102 in the emission layer 118 by preventing them from passing through the emission layer 118 and from being injected to the electron-transporting layer 122 without contributing to recombination and has a function to prevent the excitation energy obtained in the emission layer 118 from transferring to the molecules in the electron-transporting layer 122. This function prevents a decrease in emission efficiency.

It is preferable to use a material for the hole-blocking layer 120 which has higher or comparable electron-transporting properties than its hole-transporting properties and a deeper HOMO level and a larger band gap than the host material in the emission layer 118. Specifically, the difference in HOMO level between the hole-blocking material included in the hole-blocking layer 120 and the host material included in the emission layer 118 is preferred to be equal to or greater than 0.2 eV, 0.3 eV, or 0.5 eV. The difference in band gap between the hole-blocking material and the host material is preferred to be equal to or greater than 0.2 eV, 0.3 eV, or 0.5 eV. Specifically, phenanthroline derivatives, oxadiazole derivatives, triazole derivatives, metal complexes having a relatively large band gap (e.g., 2.8 eV or higher), such as bis(2-methyl-8-quinolinolato)(4-hydroxy-(4-hydroxy-biphenyl)aluminum, and the like are represented as the hole-blocking material. The hole-blocking layer 120 may also have a single-layer structure or may be composed of a plurality of layers containing different materials.

### 7. Electron-Transporting Layer

The electron-transporting layer 122 has a function of transporting the electrons injected from the cathode 104 through the electron-injection layer 124 to the emission layer 118. A (electron-accepting) compound which is easily reduced can be used for the electron-transporting layer 122. In other words, a compound with a shallow LUMO level can be used. For example, metal complexes containing a ligand with benzoquinolinol as a basic skeleton, such as tris(8-quinolinolato)aluminum and tris(4-methyl-8-quinolinolato)aluminum, metal complexes containing a ligand with oxadiazole or thiazole as a basic skeleton, and the like are represented. In addition to these metal complexes, compounds with an electron-deficient heteroaromatic ring, such as oxadiazole derivatives, thiazole derivatives, triazole derivatives, and phenanthroline derivatives, can be used. The electron-transporting layer 122 may also have a single-layer structure or may be composed of a plurality of layers containing different materials.

### 8. Electron-Injection Layer

For the electron-injection layer 124, a compound promoting electron injection from the cathode 104 to the electron-transporting layer 122 can be used. For example, a mixture of a compound which can be used for the electron-transporting layer 122 and an electron donor such as lithium and magnesium can be used. Alternatively, an inorganic compound such as lithium fluoride and calcium fluoride may be used.

The light-emitting elements containing a blue-emissive emission material exhibiting thermally activated delayed fluorescence is capable of emitting light with extremely high efficiency compared to the light-emitting elements using a conventional blue-emissive fluorescent material (i.e., a fluorescent material in which the rate of the reverse intersystem crossing from the T₁ level to the S₁ level is negligibly small and which does not substantially exhibit thermally activated delayed fluorescence). However, the driving voltage is high, and therefore, the use of a blue-emissive light-emitting element containing a thermally activated delayed fluorescent material in a display device leads to an increase in power consumption of the display device.

However, as demonstrated in the Example, the driving voltage can be reduced by selecting the host material and the emission material so that the relationships between the host material and the emission material, specifically, the aforementioned relationships regarding the band gap, the difference in LUMO level, and the difference in HOMO level are satisfied. Hence, implementation of the embodiments of the present invention allows the formation of a blue-emissive light-emitting element with high efficiency and reduced driving voltage. Therefore, the embodiment of the present invention makes it possible to produce a highly efficient display device with low power consumption.

### Second Embodiment

In this embodiment, a display device including the light-emitting element 100 described in the First Embodiment is explained. An explanation of the structures the same as or similar to those described in the First Embodiment may be omitted.

### 1. Overall Structure

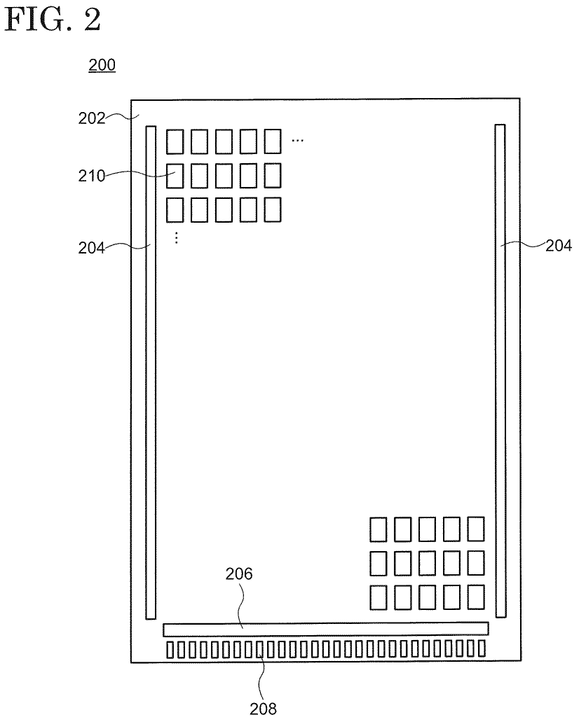

FIG. 2 shows a schematic top view of a display device 200 according to an embodiment of the present invention. As shown in FIG. 2, the display device 200 has a substrate 202, and a variety of patterned insulating films, semiconductor films, and conductor films is stacked over the substrate 202. Appropriate combination of these films results in the formation of a plurality of pixels 210, driver circuits for driving the pixels 210 (scanning-line driver circuit 204, signal-line driver circuit 206), and the like over the substrate 202. A counter substrate which is not illustrated in FIG. 2 is disposed over the pixels 210, the scanning-line driver circuit 204, and the signal-line driver circuit 206. The substrate 202 and the counter substrate are secured by a sealing material, thereby encapsulating and protecting the pixels 210, the scanning-line driver circuit 204, and the signal-line driver circuit 206. A plurality of terminals 208 formed with conductor films is provided over the substrate 202 and is electrically connected to an external circuit which is not illustrated via a connector such as a flexible printed circuit (FPC) board. A variety of signals and power supplies for displaying images are supplied from the external circuit to the scanning-line driver circuit 204 and the signal-line driver circuit 206 via the terminals 208. Note that either or both of the scanning-line driver circuit 204 and the signal-line driver circuit 206 need not be formed directly over the substrate 202, and a driver circuit formed over a substrate different from the substrate 202 (such as a semiconductor substrate) may be provided over the substrate 202 or the connector. These components are described in detail below.

### 2. Substrate and Counter Substrate

The substrate 202 and the counter substrate are provided to provide physical strength to the display device 200 and to protect the plurality of pixels 210, the scanning-line driver circuit 204, and the signal-line driver circuit 206. The substrate 202 and the counter substrate 212 may be a substrate containing an inorganic material, such as a crystalline semiconductor substrate, a glass substrate, and a quartz substrate, or may contain a polymer such as a polyimide, a polyamide, and a polycarbonate. Each of the substrate 202 and the counter substrate 212 may or may not be flexible. In the former case, the substrate 202 and/or the counter substrate 212 may be flexible enough to be elastically deformable or highly flexible enough to be plastically deformable. When the light emission from the light-emitting element is extracted to the outside through the counter substrate, at least the counter substrate 212 is configured to transmit visible light. Conversely, when the light emission from the light-emitting element is extracted to the outside through the substrate 202, at least the substrate 202 is configured to transmit visible light.

### 3.5 Pixel

The plurality of pixels 210 is configured to provide three primary colors. Specifically, the plurality of pixels 210 is configured by a plurality of red-emissive pixels, a plurality of green-emissive pixels, and a plurality of blue-emissive pixels. A pixel circuit is formed in each of the pixels 210, and one of a red-emissive light-emitting element, a green-emissive light-emitting element, and a blue-emissive light-emitting element is arranged in each of the pixels 210. As the blue-emissive light-emitting element, the light-emitting element 100 described in the First Embodiment is used. Signals for operating the pixel circuits are generated by the scanning-line driver circuit 204 and signal-line driver circuit 206 on the basis of a variety of signals supplied from an external circuit, by which the light-emitting elements connected to the pixel circuits emit light, and each pixel 210 functions as the smallest unit providing color information. As a result, full color display is realized.

### (1) Pixel Circuit

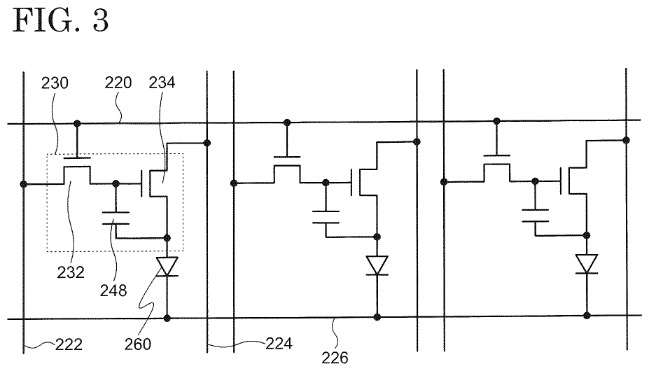

FIG. 3 shows an equivalent circuit diagram of the 210 pixels. In this drawing, an equivalent circuit diagram of three consecutively arranged pixels 210 is shown. A plurality of scanning lines 220 and a plurality of image-signal lines 222 extend from the scanning-line driver circuit 204 and signal-line driver circuit 206, respectively. The pixel circuit 230 provided in each pixel 210 is electrically connected to a corresponding one of the plurality of scanning lines 220 and a corresponding one of the plurality of image-signal lines 222.

There are no restrictions on the configuration of the pixel circuit 230, and the pixel circuit 230 may be provided with at least two transistors (switching transistor 232 and driving transistor 234) and a storage capacitor element 248 as shown in FIG. 3. Therefore, although not illustrated, the pixel circuit 230 may be further provided with one or a plurality of transistors and one or a plurality of capacitor elements. As shown in FIG. 3, a gate of the switching transistor 232 is electrically connected to the scanning line 220, and one terminal is electrically connected to the image-signal line 222. The other terminal of the switching transistor 232 is connected to one electrode (capacitor electrode) of the storage capacitor element 248 and a gate of the driving transistor 234. This structure allows a variety of signals such as image signals input via the image-signal line 222 to be input to and held in the driving transistor 234. One terminal of the driving transistor 234 is electrically connected to a current-supplying line 224, and the other terminal is electrically connected to the other electrode of the storage capacitor element 248 and a pixel electrode structuring the light-emitting element 260. The other electrode of the light-emitting element 260 is electrically connected to a common line 226 and receives a constant potential. With this configuration, the current supplied from the current-supplying line 224 flows through the light-emitting element 260 when the driving transistor 234 is on, and light emission can be obtained from each of the pixels 210. In the pixel 210 providing blue color, the light-emitting element 100 described in the First Embodiment is used as the light-emitting element 260.

### (2) Light-Emitting Element

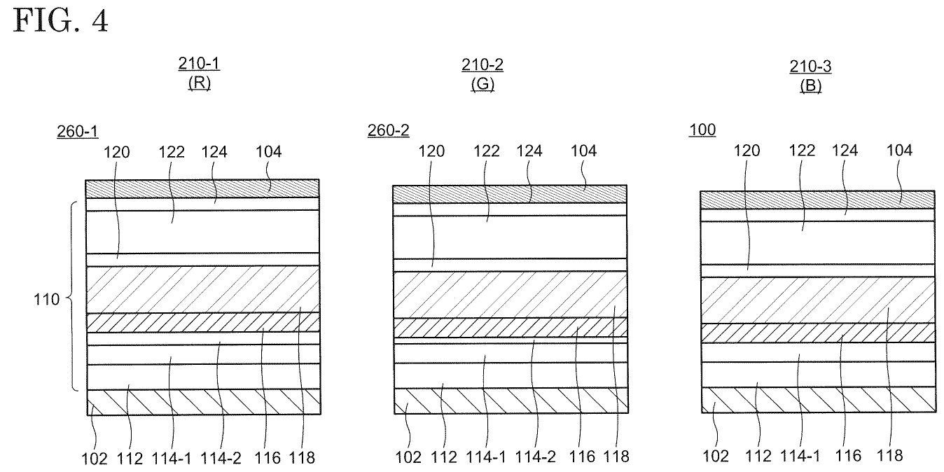

A schematic cross-sectional view of the light-emitting elements provided in the pixels 210 is shown in FIG. 4. As described above, the red-emissive pixel 210-1, the green-emissive pixel 210-2, and the blue-emissive pixel 210-3 are respectively provided with the red-emissive light-emitting element 260-1, the green-emissive light-emitting element 260-2, and the light-emitting element 100 described in the First Embodiment. There is no restriction on the configurations of the red-emissive light-emitting element 260-1 and the green-emissive light-emitting element 260-2. Similar to the light-emitting element 100, the red-emissive light-emitting element 260-1 and the green-emissive light-emitting element 260-2 have the EL layer 110 between the anode 102 and the cathode 104, and the EL layer is composed of a plurality of functional layers. Specifically, each of the EL layers 110 of the red-emissive light-emitting element 260-1 and the green-emissive light-emitting element 260-2 is composed of the hole-injection layer 112, the hole-transporting layer 114, the electron-blocking layer 116, the hole-blocking layer 120, the electron-transporting layer 122, the electron-injection layer 124, and the like in addition to the emission layer 118. Each of the EL layers 110 of the red-emissive light-emitting element 260-1 and the green-emissive light-emitting element 260-2 may have all or some of the functional layers described above. The materials used in these functional layers are as described in the First Embodiment. However, since the emission wavelengths are different, the emission material, the structure of the emission layer 118 containing the emission material, the structures of the functional layers adjacent to the emission layer 118 (e.g., the electron-blocking layer 116 and the hole-blocking layer), the structures (thicknesses) of the hole-transporting layer 114 and the electron-transporting layer 122 are adjusted accordingly in the red-emissive light-emitting element 260-1 and the green-emissive light-emitting element 260-2.

For example, the thickness of the hole-transporting layer 114 may be set to be larger for the red-emissive light-emitting element 260-1 and the green-emissive light-emitting element 260-2 providing longer wavelength emission compared with the light-emitting element 100. Specifically, the pixels 210 may be configured so that the thickness of the hole-transporting layer 114 increases in the order of the light-emitting element 100, the green-emissive light-emitting element 260-2, and the red-emissive light-emitting element 260-1. For example, a plurality of hole-transporting layers 114 (in the example shown in FIG. 4, first hole-transporting layer 114-1 and second hole-transporting layer 114-2) may be provided in the red-emissive light-emitting element 260-1 and the green-emissive light-emitting element 260-2. The first hole-transporting layer 114-1 is commonly provided across all of the pixels 210, and the thickness of the second hole-transporting layer 114-2 in the red-emissive light-emitting element 260-1 is set to be larger than that in the green-emissive light-emitting element 260-2, by which the number of metal masks used to form the hole-transporting layer 114 can be reduced, and a resonance structure suitable for the emission wavelength can be formed between the anode 102 and the emission layer 118 for each of the 210 pixels.

In both or at least one of the red-emissive light-emitting element 260-1 and the green-emissive light-emitting element 260-2, a phosphorescent material is used as the emission material. The use of a phosphorescent material can utilize light emission from a triplet excited state formed in the emission layer 118, resulting in highly efficient emission. In this case, the emission layer 118 is configured so that the band gap of the host material is larger than that of the emission material and the T₁ level of the host material is shallower than the T₁ level of the emission material.

For example, in addition to zinc- and aluminum-based metal complexes, oxadiazole derivatives, triazole derivatives, benzimidazole derivatives, quinoxaline derivatives, dibenzoquinoxaline derivatives, dibenzothiophene derivatives, dibenzofuran derivatives, pyrimidine derivatives, triazine derivatives, pyridine derivatives, bipyridine derivatives, phenanthroline derivatives, aromatic amine derivatives, carbazole derivatives, and the like may be used as the host material.

Phosphorescent materials such as iridium-based ortho-metal complexes, platinum porphyrin complexes, and rare earth complexes may be used as the emission material. For example, iridium complexes with a pyrimidine skeleton such as (diisobutyrylmethanato)bis[4,6-bis(3-methylphenyl)pyrimidinato]iridium(III) and bis[4,6-bis(3-methylphenyl)pyrimidinato](dipivaroylmethanato)iridium(III), iridium complexes with a pyrazine skeleton such as (acetylacetonato)bis(2,3,5-triphenylpyrazinato)iridium(III) and bis(2,3,5-triphenylpyrazinato)(dipivaroylmethanato)iridium(III), iridium complexes with a pyridine skeleton such as tris(1-phenylisoquinolinato-N,C2′)Iridium(III) and bis(1-phenylisoquinolinato-N,C2′)iridium(III) acetylacetonate may be used as the emission materials capable of red emission. Alternatively, platinum complexes such as 2,3,7,8,12,13,17,18-octaethyl-21H,23H-porphyrin platinum (II), and rare earth metal complexes such as tris(1,3-diphenyl-1,3-propanedionato)(monophenanthroline)europium(III) and tris[1-(2-tenoyl)-3,3,3-trifluoroacetonato](monophenanthroline)europium(III) may be used.

As the emission materials capable of green emission, rare earth metal complexes such as tris(acetylacetonato)(monophenanthroline) terbium(III) may be used in addition to iridium complexes with a pyrimidine skeleton such as tris(4-methyl-6-phenylpyrimidinato)iridium(III) and tris(4-t-butyl-6-phenylpyrimidinato)iridium(III), iridium complexes with a pyrazine skeleton such as (acetylacetonato)bis(3,5-dimethyl-2-phenylpyrazinato)iridium(III) and (acetylacetonato)bis(5-isopropyl-3-methyl-2(phenylpyrazinato)iridium(III), iridium complexes with a pyridine skeleton such as tris(2-phenylpyridinato-N,C2′)iridium(III) and bis(2-(phenylpyridinato-N,C2′)iridium(III) acetylacetonate.

Alternatively, a thermally activated delayed fluorescent material may be used in both or at least one of the red-emissive light-emitting element 260-1 and the green-emissive light-emitting element 260-2. In this case, the emission layer 118 is also configured so that the band gap of the host material is larger than that of the emission material and the T₁ level of the host material is higher than that of the emission material. Among the thermally activated delayed fluorescent materials described in the First Embodiment, the red-emissive and green-emissive emission materials may be respectively used in the red-emissive light-emitting element 260-1 and the green-emissive light-emitting element 260-2 as the thermally activated delayed fluorescent material. The use of the thermally activated delayed fluorescent materials promotes the reverse intersystem crossing from the T₁ level to the S₁ level of the thermally activated delayed fluorescent material formed in the emission layer 118 and allows the emission from the S₁ level to be used, thereby resulting in highly efficient emission.

In addition, similar to the light-emitting element 100, the emission layers 118 of the red-emissive light-emitting element 260-1 and the green-emissive light-emitting element 260-2 may further contain a fluorescent material (second fluorescent material) which does not exhibit thermally activated delayed fluorescence. Examples of the second fluorescent materials suitable for the red-emissive light-emitting element 260-1 include pyran derivatives, tetracene derivatives, anthraquinone derivatives, and the like. Coumarin derivatives, quinacridone derivatives, anthracene derivatives, pyrene derivatives, and the like are exemplified as the second fluorescent material suitable for the green-emissive light-emitting element 260-2.

The electron-blocking layer 116, the electron-transporting layer 122, the electron-injection layer 124, and the cathode 104 may be provided to be shared by all of the pixels 210 or may be formed so as to be independent in one pixel 210 selected from the pixels 210-1, 210-2, and 210-3 but to be shared by the other two pixels 210. The formation of the functional layers to be shared by the pixels having different emission colors reduces the number of metal masks, thereby enabling the production of the display device 200 at a lower cost.

Although not illustrated, one or a plurality of cap layers may be provided over the cathode 104 in each pixel 210 so as to be in contact with the cathode 104. The formation of the cap layer allows the light emitted from the emission layer 118 to resonate through repeated reflection between the top surface and the bottom surface of the cap layer. This mechanism increases the luminance in the frontal direction of the display device 200 and improves color purity. The material of the cap layer is selected so that the cap layer transmits at least part of visible light. For example, a material included in the functional layers or a polymer such as an acrylic resin, an epoxy resin, and a silicon resin may be used. Alternatively, a polymeric material containing fluorine may be used. Alternatively, inorganic compounds exemplified by metal fluorides such as lithium fluoride, magnesium fluoride, and calcium fluoride may be included instead of organic compounds. The cap layer may be provided so as to have the same structure in all of the pixels 210. Alternatively, a first cap layer may be provided in some of the pixels 210 selected from these pixels 210, and a second cap layer may be further provided to be shared by all of the pixels 210. This structure provides the cap layer with a resonance structure more suitable for the emission wavelength.

### (3) Cross-Sectional Structure of Pixel

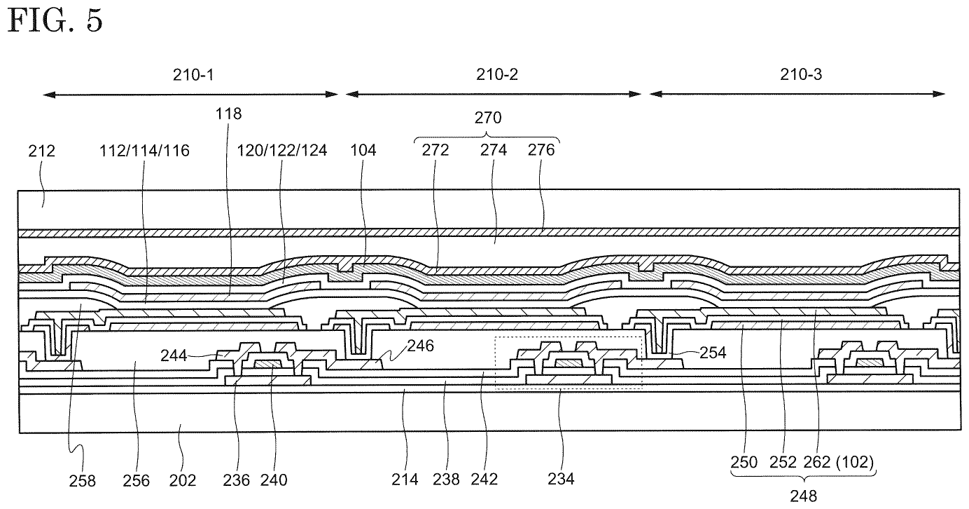

A schematic view of a cross section of the display device 200 is shown in FIG. 5. Here, three consecutively arranged pixels 210-1, 210-2, and 210-3 are schematically depicted. In the example shown in FIG. 5, the pixel circuit 230 including the driving transistor 234 is provided over the substrate 202 through an undercoat 214 which is an optional component. The driving transistor 234 shown in FIG. 5 is composed of a semiconductor film 236, a gate insulating film 238 over the semiconductor film 236, a gate electrode 240 over the gate insulating film 238, an interlayer insulating film 242 over the gate electrode 240, and a pair of terminals 244 and 246 provided over the interlayer insulating film 242 and electrically connected to the semiconductor film 236. Although the driving transistor 234 shown here is a top-gate type transistor, there is no restriction on the structure of the driving transistor 234, and a bottom-gate type transistor or a transistor having gate electrodes over and under the semiconductor film may be used as the driving transistor 234.

A leveling film 256 is provided over the driving transistor 234 to absorb unevenness caused by the pixel circuit 230 and provide a flat surface. A capacitance electrode 250, a capacitance insulating film 252 over the capacitance electrode 250, and the pixel electrode 262 may be arranged over the leveling film 256, and the storage capacitor element 248 are structured by these components. Here, the pixel electrode 262 functions as the anode 102 of the light-emitting element 100, the red-emissive light-emitting element 260-1, and the green-emissive light-emitting element 260-2. Therefore, each pixel electrode 262 is shared by the light-emitting element 100, the red-emissive light-emitting element 260-1, or the green-emissive light-emitting element 260-2 and the storage capacitor element 248. An opening is formed in the leveling film 256 to expose the terminal 246, and the pixel electrode 262 is electrically connected to the terminal 246 at this opening either directly or through a connecting electrode 254 covering this opening. A partition wall 258 which is an insulating film is provided to cover an edge portion of the pixel electrode 262, and the EL layer 110 is arranged to cover the pixel electrode 262 and the partition wall 258. This structure electrically insulates the adjacent light-emitting elements 100 and prevents the EL layer 110 from being cleaved by the edge portion of the pixel electrode 262.

Although some functional layers except for the emission layer 118 are shown as a single layer for visibility in FIG. 5, the red-emissive light-emitting element 260-1, the green-emissive light-emitting element 260-2, and the light-emitting element 100 are respectively arranged in the red-emissive pixel 210-1, the green-emissive pixel 210-2, and the blue-emissive pixel 210-3 as described above. The cathode 104 is provided to be shared by all of the pixels 210. As an optional component, a sealing film 270 may be formed over the cathode 104 either directly or via the cap layer which is not illustrated. There are no restrictions on the structure of the sealing film 270. For example, a film containing a silicon-containing inorganic compound such as silicon nitride or a film containing a resin such as epoxy resin and an acrylic resin may be used to structure the sealing film 270. In the example shown in FIG. 5, the sealing film 270 in which a resin-containing film 274 is sandwiched between films 272 and 276 containing a silicon-containing inorganic compound is used. The counter substrate 212 is provided over the cathode 104 via the sealing film 270 and/or the cap layer, and the substrate 202 and the counter substrate 212 are secured to each other using a sealing material which is not illustrated, thereby. protecting the pixels 210.

As described in the First Embodiment, the blue-emissive light-emitting element 100 exhibits extremely high efficiency because it contains a thermally activated delayed fluorescent material. In addition, the host material and the emission material included in the emission layer 118 of the light-emitting element 100 are configured to satisfy the relationships described in the First Embodiment with respect to the LUMO level, the HOMO level, and the band gap. Therefore, as demonstrated in the Example, the light-emitting element 100 can be driven at a lower voltage and has improved emission efficiency compared with conventional blue-emissive light-emitting elements including a thermally activated delayed fluorescent material in the emission layer. Therefore, implementation of the embodiment of the present invention enables the production of a full-color electroluminescent device with low power consumption.

### EXAMPLES

Light-emitting elements according to the Example and the Comparative Example were fabricated and their characteristics were evaluated. The functional layers structuring these light-emitting elements and their thicknesses are listed in Table 1. In both light-emitting elements, an ITO thin film (50 nm thickness) was used as the anode, and a co-evaporation film of silver and magnesium (160 nm thickness) was used as the cathode. The size of the emission region was 2 mm×2 mm. In both light-emitting elements, the emission layers contain a host material, a blue-emissive thermally activated delayed fluorescent material, and a blue-emissive fluorescent material (i.e., the second fluorescent material which does not exhibit thermally activated delayed fluorescence). However, the host material of the light-emitting element of the Comparative Example was a host material generally used for blue-emissive fluorescent light-emitting elements, whereas the host material of the light-emitting element of the Example was a host material generally used for green-emissive phosphorescent light-emitting elements. Therefore, in the light-emitting element of the Example, the relationships described in the First Embodiment are established between the host material and the thermally activated delayed fluorescent material with respect to the band gap, the LUMO level, and the HOMO level. In contrast, in the light-emitting element of the Comparative Example, the difference in LUMO level between the host material and the thermally activated delayed fluorescent material was 1.0 eV, and the difference in HOMO level therebetween was 0.3 eV.

The same materials were used for the hole-injection layer, the hole-transporting layer, the hole-blocking layer, the electron-transporting layer, and the electron-injection layer between the light-emitting elements of the Example and the Comparative Example, and the thicknesses thereof were also the same. In order to prevent the accumulation of a large amount of carriers in both light-emitting elements, the electron-blocking layer was formed so that the difference in LUMO level between the host material of the emission layer and the material included in the electron-blocking layer was equal to or greater than 0.1 eV and equal to or less than 0.2 eV.

TABLE 1
Thicknesses of functional layers of light-emitting
elements of Example and Comparable example (nm).

| | Hole- | Hole- | Electron- | | Hole- | Electron- | Electron- |
|---|---|---|---|---|---|---|---|
| | injection | transporting | blocking | Emission | blocking | transporting | injection |
| Sample | layer | layer | layer | layer | layer | layer | layer |
| Comparable | 17 | 30 | 5 | 45 | 10 | 20 | 2 |
| example | | | | | | | |
| Example | 17 | 30 | 5 | 45 | 10 | 20 | 2 |

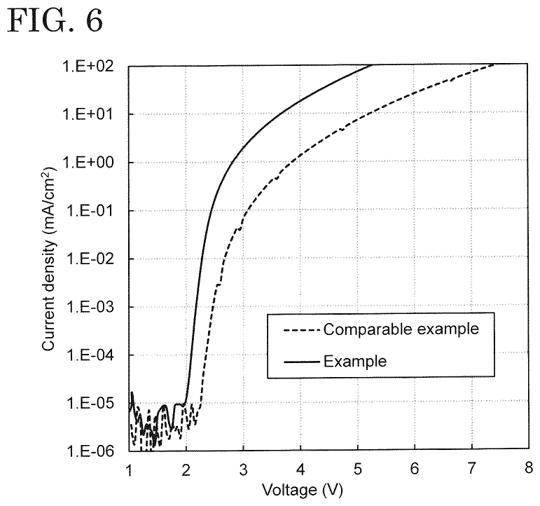

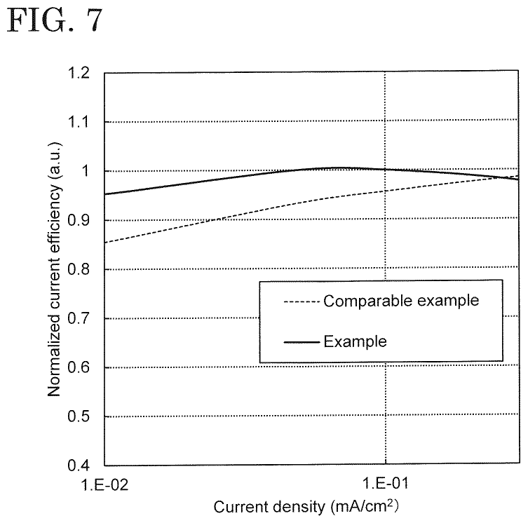

The voltage-current density curves of the fabricated light-emitting elements are shown in FIG. 6. FIG. 6 reveals that the driving voltage of the light-emitting element of the Example is significantly reduced compared with the light-emitting element of the Comparison example. For example, when a current is applied to the light-emitting elements at a current density of 1 mA/cm², the difference in driving voltage reaches about 1.2V. As can be understood from the current density-normalized emission efficiency curves shown in FIG. 7, the emission efficiency of the light-emitting element of the Example is higher than that of the Comparative Example. In particular, the increase in emission efficiency at a low current density is remarkable, which suggests that non-radiative recombination of carriers accumulated at the interface of functional layers (mainly the interface between the emission layer and the electron-blocking layer) is suppressed in the light-emitting element of the Example.

The above results show that application of the embodiments of the present invention enables the production of light-emitting elements with low power consumption and improved emission efficiency as well as low-power-consumption display devices including these light-emitting elements.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the reflecting element or the reflecting device of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising:
an anode, a cathode, and an electroluminescent layer located between the anode and the cathode and including an emission layer containing a host material and a first fluorescent material,
wherein the first fluorescent material exhibits thermally activated delayed fluorescence,
a bandgap of the host material is equal to or greater than 3.0 eV and equal to or less than 3.4 eV,
a level of a lowest unoccupied molecular orbital of the host material is shallower than a level of a lowest unoccupied molecular orbital of the first fluorescent material and a difference therebetween is equal to or less than 0.3 eV, and
a level of a highest occupied molecular orbital of the host material is shallower than a level of a highest occupied molecular orbital of the first fluorescent material and a difference therebetween is equal to or greater than 1.0 eV.

2. The light-emitting element according to claim 1,
wherein the host material is configured so that a hole-transporting property is higher than an electron-transporting property.

3. The light-emitting element according to claim 1,
wherein an energy difference between the lowest singlet excited state and the lowest triplet excited state of the first fluorescent material is equal to or greater than 5 meV and equal to or less than 20 meV.

4. The light-emitting element according to claim 1,
wherein the emission layer further contains a second fluorescent material.

5. The light-emitting element according to claim 1,
wherein the electroluminescent layer further includes an electron-blocking layer between the emission layer and the anode and in contact with the emission layer, and
a level of a lowest unoccupied molecular orbital of the electron-blocking layer is shallower than the level of the lowest unoccupied molecular orbital of the host material and a difference therebetween is equal to or less than 0.2 eV.

6. The light-emitting element according to claim 4,
wherein the second fluorescent material exhibits a multiple resonance effect.

7. The light-emitting element according to claim 6,
wherein the second fluorescent material contains boron and nitrogen.

8. A display device comprising a red-emissive pixel, a green-emissive pixel, and a blue-emissive pixel respectively including a red-emissive light-emitting element, a green-emissive light-emitting element, and a blue-emissive light-emitting element,
wherein the blue-emissive light-emitting element comprises an anode, a cathode, and an electroluminescent layer between the anode and the cathode,
the electroluminescent layer comprises an emission layer containing a host material and a first fluorescent material,
the first fluorescent material exhibits thermally activated delayed fluorescence,
a bandgap of the host material is equal to or greater than 3.0 eV and equal to or less than 3.4 eV,
a level of a lowest unoccupied molecular orbital of the host material is shallower than a level of a lowest unoccupied molecular orbital of the first fluorescent material and a difference therebetween is equal to or less than 0.3 eV, and
a level of a highest occupied molecular orbital of the host material is shallower than a level of a highest occupied molecular orbital of the first fluorescent material and a difference therebetween is equal to or greater than 1.0 eV.

9. The display device according to claim 8,
wherein the host material is configured so that a hole-transporting property is higher than an electron-transporting property.

10. The display device according to claim 8,
wherein an energy difference between a lowest singlet excited state and a lowest triplet excited state of the first fluorescent material is equal to or greater than meV and equal to or less than 20 meV.

11. The display device according to claim 8,
wherein the emission layer further contains a second fluorescent material.

12. The display device according to claim 8,
wherein the electroluminescent layer further includes an electron-blocking layer between the emission layer and the anode and in contact with the emission layer, and
a level of a lowest unoccupied molecular orbital of the electron-blocking layer is shallower than the level of the lowest unoccupied molecular orbital of the host material and a difference therebetween is equal to or less than 0.2 eV.

13. The display device according to claim 11,
wherein the second fluorescent material exhibits a multiple resonance effect.

14. The display device according to claim 13,
wherein the second fluorescent material contains boron and nitrogen.

15. The display device according to claim 8,
wherein the red-emissive light-emitting element comprises an anode, a cathode, and an electroluminescent layer between the anode and the cathode, and
the electroluminescent layer of the red-emissive light-emitting element contains a phosphorescent material.

16. The display device according to claim 8,
wherein the red-emissive light-emitting element comprises an anode, a cathode, and an electroluminescent layer between the anode and the cathode, and
the electroluminescent layer of the red-emissive light-emitting element contains a fluorescent material exhibiting thermally activated delayed fluorescence.

17. The display device according to claim 8,
wherein the green-emissive light-emitting element comprises an anode, a cathode, and an electroluminescent layer between the anode and the cathode, and
the electroluminescent layer of the green-emissive light-emitting element contains a phosphorescent material.

18. The display device according to claim 8,
wherein the green-emissive light-emitting element comprises an anode, a cathode, and an electroluminescent layer between the anode and the cathode, and
the electroluminescent layer of the green-emissive light-emitting element contains a fluorescent material exhibiting thermally activated delayed fluorescence.
